(19) United States
(12) Patent Application Publication
(10) Pub. No.: US 2002/0074938 A1
(43) Pub. Date: Jun. 20, 2002

(54) Night or safety light with patternable illumination regions

(76) Inventor: Gong Gu, Bridgewater, NJ (US)

Correspondence Address: ATTN.: GLEN E. BOOKS, ESQ., MATHEWS, COLLINS, SHEPHERD & GOULD, P.A., SUITE 306, 100 THANET CIRCLE, PRINCETON, NJ, 08540, US

(21) Appl. No.: 09/741,522

(22) Filed: Dec. 20, 2000

(51) Int. Cl. H01J 63/04

(52) U.S. Cl. 313/512; 313/504

(57) ABSTRACT

In accordance with the invention, a night-light or safety light comprises a layer of organic semiconducting material including a light-emitting organic semiconductor disposed between a substrate-supported bottom electrode and a top electrode. Electricity (AC or DC) applied between the electrodes stimulates low-level illumination. The electrodes or the organic material can be patterned to display text or aesthetic design, and a plurality of different organic light emitting materials can patterned to produce a multicolored pattern.

### FIELD OF THE INVENTION

This invention relates to night-lights and safety lights for providing low-level safety illumination in homes, businesses and vehicles, and, in particular, to lights using organic light-emitting material. Advantageous embodiments can provide patternable illumination regions and multicolored patterns.

### BACKGROUND OF THE INVENTION

Night-lights and safety lights are useful in providing orientation in a darkened building or vehicle and guidance in the event of an unexpected power failure. These lights have traditionally used incandescent bulbs although some recently marketed devices use crystalline semiconductor light-emitting diodes.

Both bulb-based and crystalline semiconductor diode lights are expensive to fabricate and limited in design flexibility. Bulb-based lights require numerous mechanical processing steps. Diode lights are typically limited to a single color. Accordingly there is a need for night-lights and safety lights that are inexpensive to fabricate, and it would be advantageous if such lights could provide patterned illumination regions in one or more colors.

### SUMMARY OF THE INVENTION

In accordance with the invention, a night-light or safety light comprises a layer of organic semiconducting material including a light-emitting organic semiconductor disposed between a substrate-supported bottom electrode and a top electrode. Electricity (AC or DC) applied between the electrodes stimulates low-level illumination. The electrodes or the organic material can be patterned to display text or aesthetic design, and a plurality of different organic light emitting materials can patterned to produce a multicolored pattern.

### BRIEF DESCRIPTION OF THE DRAWINGS

The advantages, nature and various additional features of the invention will appear more fully upon consideration of the illustrative embodiments now to be described in detail in connection with the accompanying drawings. In the drawings:

FIG. 1 is a schematic cross section of a typical illumination source for a light in accordance with the invention;

FIG. 2 is a schematic flow diagram of the steps involved in an exemplary process for making the source of FIG. 1;

FIG. 3A and 3B are front and side views of a typical night-light or safety light employing the source of FIG. 1;

FIG. 4 schematically illustrates an exemplary electrical connection arrangement for the light of FIGS. 3A and 3B; and

FIG. 5 is a schematic cross-section of an alternative illumination source.

It is to be understood that these drawings are for purposes of illustrating the concepts of the invention and are not to scale.

### DETAILED DESCRIPTION

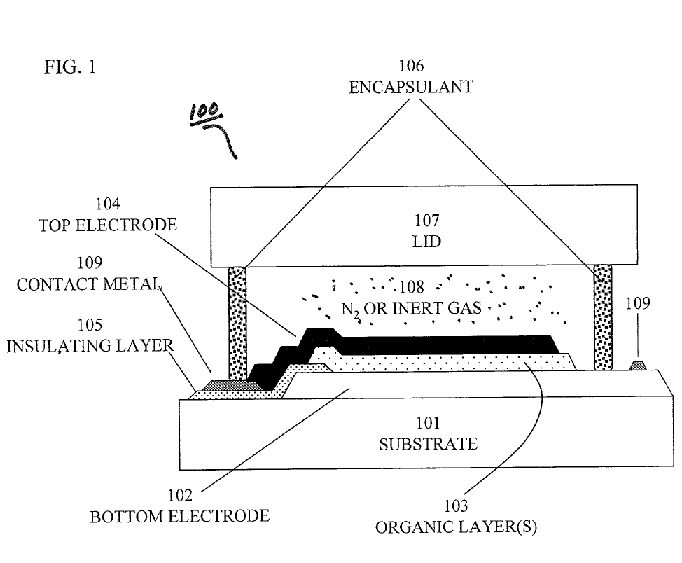

Referring to the drawings, FIG. 1 is a schematic cross section of an illumination source 100 comprising a substrate 101 supporting a bottom electrode 102, a layer of one or more organic semiconducting material(s) 103 and a top electrode 104 in electrical contact with the organic material(s) 103. The term organic semiconducting material as used herein refers to an organic material exhibiting weak electron or hole conductivity. At least one of the electrodes 102, 104 is transparent for light emission. An insulating spacer layer 105 is conveniently provided to keep bottom electrode 102 from shorting with top electrode 104, and the layer of organic material(s) 103 is encapsulated by an air impermeable encapsulant 106 and an impermeable lid 107 to retain an inert gas ambient 108. Either the substrate 101 or the lid 107 is transparent. Contact metal 109 is advantageously deposited for wire bonding. The layer 103 can be a composite of organic semiconducting layers, at least one of which is light-emitting material.

The substrate 101 can be any impermeable insulating material such as glass or plastic and is preferably polyester. The bottom electrode 102 can be any conductive material compatible with the substrate, and is preferably indium tin oxide (ITO). Glass or plastic (e.g. polyester) sheets precoated with ITO are commercially available. The organic layers preferably comprise a hole transport layer (HTL) such as 4,4′-bis[N-(1-napthyl)-N-phenyl-amino]biphenyl (α-NPD), and an electron transport and light-emitting layer (ETL/LL) such as tris-(8-hydroxyquinoline) aluminum (Alq₃). The HTL and ETL/LL thicknesses are preferably in the range of 200 to 500 Å. Alternatively, a single carrier transport and light-emitting layer can be used. This single organic layer preferably comprises a hole transporting layer such as poly(N-vinylcarbazole)(PVK) and contains dispersed electron transporting molecules such as 2-(4-biphenyl)-5-(4-tert-butylphenyl)-1,3,4-oxadiazole (PBD) and a fluorescent dye such as coumarin 6. The top electrode 104 can be any conductive material but is preferably a layer of Mg:Ag alloy having a thickness in the range of 1000 to 2000 Å. The encapsulant 106 can be epoxy, and the lid 107 can be glass or a plastic such as polyester. The inert gas ambient can be a relatively inert gas such as N₂ or a true inert gas such as argon.

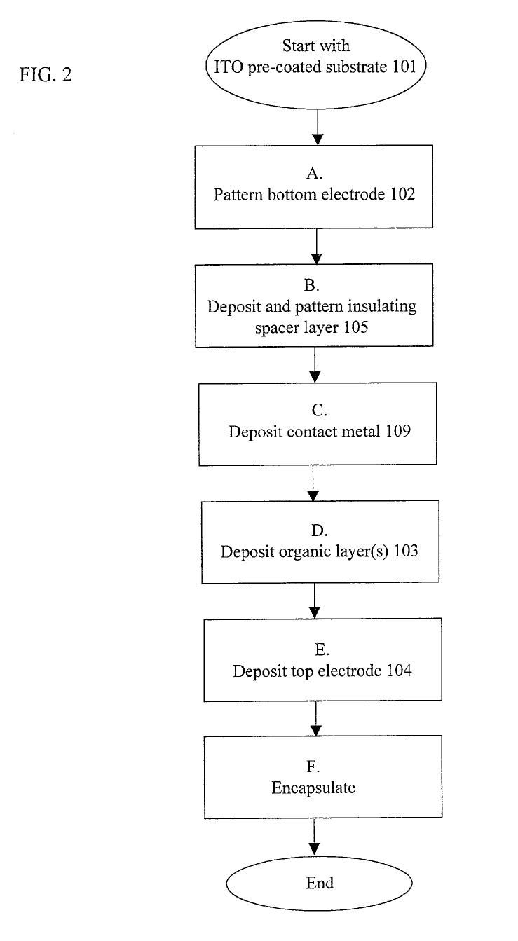

FIG. 2 is a schematic flow diagram of the steps involved in an exemplary process for making the light source 100 of FIG. 1. The process starts with a commercially available polyester sheet 101 pre-coated with an ITO film 102. The first step, shown in Block A of FIG. 1, is to pattern the bottom electrode 102. This can be done by photolithography and wet or dry etching in accordance with techniques well known in the art.

The second step, shown in Block B, is to deposit and pattern insulating spacer layer 105. The layer 105 can be SiNₓ deposited and patterned by well-known techniques.

The next step (Block C) is to deposit and pattern contact metal 109 to form bonding pads.

The fourth step (Block D) is to form the layer(s) of organic material(s) 103. The materials can be deposited by spin coating, vacuum deposition, organic vapor phase deposition or ink jet printing. Organic materials emitting in different colors can be selectively deposited and patterned to form a multi-colored light pattern. Usually only the ETL/LL needs to be patterned in the case of multiple organic layers.

The next step (Block E) is to form the top electrode layer 104. It can be a layer of low work function metal or alloy probably capped by a relatively inactive metal film such as Ag. The top electrode can be deposited through a shadow mask to form a graphic or text pattern.

The sixth step shown in Block F of FIG. 2 is to encapsulate the light emitting region in inert gas and finish the device. This involves applying encapsulating material 106, such as epoxy, around the periphery of the light-emitting region. The lid 107 can then be joined to the epoxy in a dry nitrogen or inert gas atmosphere to form a hermetic encapsulation. In the case of a plastic substrate and lid, a watertight film such as SiO₂ may be deposited over the outer surfaces to ensure hermetic encapsulation.

Once the light source 100 is complete, a night-light or safety light is finished by attaching the source 100 to an appropriate package including plug blades for an electrical power outlet.

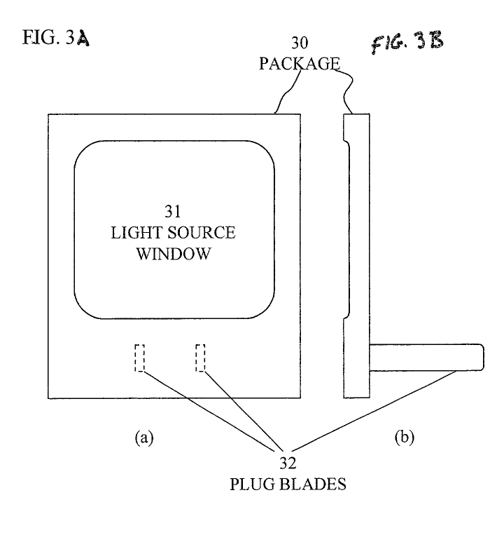

FIG. 3A and 3B are front and side views of an exemplary finished light comprising a package 30 with an open window 31 for the light source 100. Plug blades 32 are dimensioned to fit into a standard electrical outlet. Electrical wires (not shown) connect the light source 100 to a voltage down converter/rectifier (not shown), which, in turn, is connected to the blades 32.

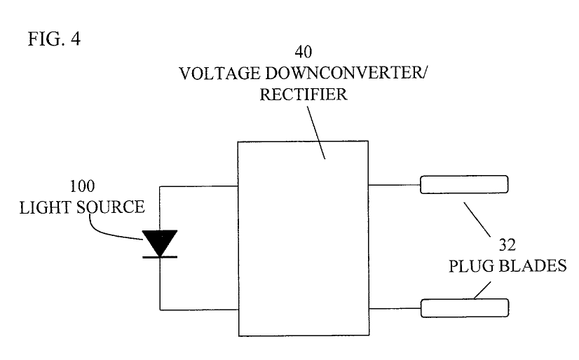

FIG. 4 illustrates. the electrical connection of the light source 100 (represented as an organic light emitting diode—an OLED), a voltage down converter/rectifier 40, and the plug blades 32. The light source 100 is represented by one diode symbol, although the light source may consist of multiple OLEDs in parallel in the case of multi-color light source. In order to supply electric power to the light source 100, a voltage down converter/rectifier 40 down converts electricity from the AC voltage of ˜110 V (or 220 V, depending on the country where the night light is to be used) to an AC voltage of a few volts to about 20 volts, and possibly rectifies the down converted AC voltage to a single polarity pulse or DC voltage. A transformerless down converter/rectifier, composed of a capacitor and a rectifying bridge or diode, is preferred for compactness and light weight. Rectification is not necessary since the light sources can operate at AC voltages. Pulsed or AC operation may be preferred for simplicity and elongated lifetime. The input terminals of the voltage downconverter/rectifier are connected to the plug blades 32.

### ALTERNATIVE EMBODIMENT

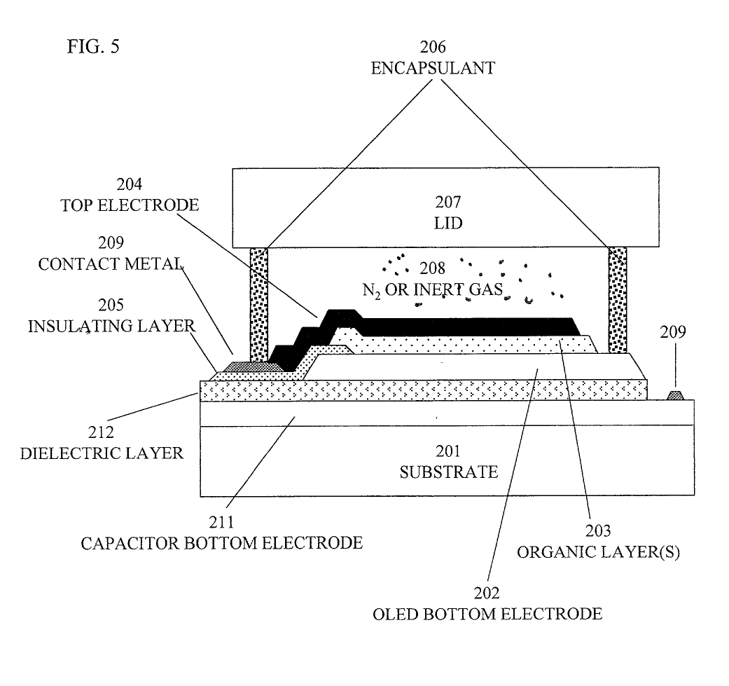

FIG. 5 shows the cross-section of an alternative light source 200 comprising a substrate 201 supporting a capacitor bottom electrode 211, a dielectric layer 212, an OLED bottom electrode 202 (electrode 202 is also the top electrode for the capacitor), a single or composite layer of organic semiconducting material(s) 203 in electrical contact with the bottom electrode 202, (in the case of multiple organic layers, only one layer is in contact with the bottom electrode 202). A top electrode 204 is disposed in electrical contact with the organic material 203 or the topmost layer of 203 in the case of composite organic layers. The substrate 201, electrodes 211 and 202, and the dielectric layer 212 are transparent for light emission. An insulating spacer layer 205 is conveniently provided to keep bottom electrode 202 from shorting with top electrode 204, and the organic materials 203 should be encapsulated within an air impermeable encapsulant 206 and an impermeable lid 207 to retain an inert gas ambient 108 around the light emitting material. Contact metal 209 is deposited for wire bonding.

In this embodiment, the electrodes 211 and 202 and the dielectric layer 212 form a capacitor, which will assume most of the applied AC voltage and thereby reduce the voltage across the organic layer. Hence, no voltage down converter is needed, and contacts 209 are directly connected to the plug blades 32. The capacitance value and hence thickness of layer 212 are determined by the OLED resistance and operating voltage, and by the total applied AC voltage. In light source 200, parts 203 through 209 are identical to 103 through 109 in light source 100.

Fabrication of light source 200 starts with a commercially available polyester sheet 201 pre-coated with an ITO film 211. The first step is to deposit and pattern the dielectric layer 212. This can be done by selectively depositing a dielectric such as SiNₓ through a shadow mask, leaving uncovered area for later deposition of contact 209 to the capacitor bottom electrode 211.

The second step is to deposit and pattern the OLED bottom electrode 202. This can be done by sputtering or thermal evaporation through a shadow mask.

The next steps are identical to the process steps illustrated by Blocks B through F in FIG. 2.

Once the light source 200 is complete, a night-light or safety light is finished by attaching the source 200 to an appropriate package including plug blades for an electrical power receptacle.

The light source 200 is packaged as shown in FIGS. 3A and 3B. Plug blades 32 are dimensioned to fit into a standard electrical outlet. Electrical wires (not shown) connect the light source 200 to the blades 32.

It is to be understood that the above-described embodiments are illustrative of only a few of the many possible specific embodiments, which can represent applications of the principles of the invention. Numerous and varied other arrangements can be readily devised by those skilled in the art without departing from the spirit and scope of the invention.

What is claimed is:

1. A light for providing low-level illumination comprising:
a first electrode,
an organic layer in electrical contact with the first electrode, the organic layer comprising one or more organic semiconducting materials and including at least one light-emitting organic material;
a second electrode in electrical contact with the organic layer; and
an enclosure surrounding the organic layer, the enclosure containing an ambient of inert gas or nitrogen and having at least one transparent region through which emitted light can pass.

2. The light of claim 1 further comprising a substrate for supporting the first electrode or the second electrode.

3. The light of claim 1 wherein the first electrode or the second electrode is transparent to emitted light.

4. The light of claim 1 wherein the organic layer comprises a hole transport layer and an electron transport layer.

5. The light of claim 2 wherein the substrate comprises glass or plastic.

6. The light of claim 2 wherein the substrate comprises a plastic sheet supporting an indium tin oxide electrode.

7. The light of claim 1 wherein the electrodes are electrically connected to plug blades for an electrical power receptacle via a voltage down converter.

8. The light of claim 2 wherein the substrate further comprises a conductive layer and a dielectric layer for forming a capacitor to reduce the voltage across the organic layer.

9. The light of claim 8 wherein the electrodes are directly connected to plug blades for an electrical power receptacle.
